(19) United States
(12) Patent Application Publication
(10) Pub. No.: US 2018/0226468 A1
(43) Pub. Date: Aug. 9, 2018

(54) CAPACITOR DEPOSITION APPARATUS AND DEPOSITION METHOD OF DIELECTRIC FILM USING SAME

(71) Applicant: JUSUNG ENGINEERING CO., LTD., Gwangju-si, Gyeonggi-do (KR)

(72) Inventors: Dong Won SEO, Gwangju-si, Gyeonggi-do (KR); Jae Chan KWAK, Gwangju-si, Gyeonggi-do (KR); Byoung Ha CHO, Gwangju-si, Gyeonggi-do (KR)

(21) Appl. No.: 15/748,649

(22) PCT Filed: Jul. 18, 2016
(86) PCT No.: PCT/KR2016/007783

§ 371 Date: Jan. 29, 2018

(30) Foreign Application Priority Data
Jul. 27, 2015 (KR) 10-2015-0106099
Nov. 5, 2015 (KR) 10-2015-0155265

(51) Int. Cl. H01L 49/02; H01L 21/02

(52) U.S. Cl. CPC H01L 28/60; H01L 21/02315; H01L 21/0234

(57) ABSTRACT

Disclosed is a method of manufacturing a capacitor having a high dielectric constant, which prevents a surface of a dielectric layer from being deteriorated due to a vacuum break and prevents the quality of a dielectric layer from being degraded due to a physical stress occurring when a semiconductor substrate is being loaded and unloaded.

### TECHNICAL FIELD

The present invention relates to a capacitor deposition apparatus and a method of depositing a dielectric layer deposition by using the same.

### BACKGROUND ART

As a degree of integration of semiconductor devices increases progressively, an area occupied by a device is progressively reduced. In semiconductor memory devices (for example, dynamic random access memory (DRAM), an area of a device is reduced, but a fundamentally necessary capacity of a capacitor should be secured. Therefore, various methods are be researched for complementing a capacity of a capacitor which is reduced due to a reduction in area of a device.

A capacity of a capacitor is defined as expressed in the following Equation (1):

$$C = ɛ \frac{A}{t} \qquad [ Equation 1 ]$$

where ε denotes a dielectric constant of a dielectric layer, A denotes an area of an electrode, and t denotes a thickness of the dielectric layer. In order to increase the capacity of the capacitor, a material which is high in dielectric constant should be used as a dielectric layer, the dielectric layer should be thinly formed, or the area of the electrode should increase. However, since an area of a device is recently reduced due to an increase in degree of integration of semiconductor devices as described above, it is difficult to enlarge the area of the electrode, and for this reason, the capacity of the capacitor increases by thinly forming a dielectric layer or using a dielectric layer which is high in dielectric constant.

The capacitor includes a first electrode which is a lower electrode, a second electrode which is an upper electrode, and a dielectric layer formed between the first electrode and the second electrode. The first electrode, the dielectric layer, and the second electrode are respectively formed in different chambers. For this reason, a vacuum break exists until the second electrode is formed after the dielectric layer is formed, and in this case, the dielectric layer is exposed to air during the vacuum break, causing oxidation or deterioration of the dielectric layer.

Moreover, as the number of times a semiconductor substrate is unloaded and loaded increases, a physical stress applied to the semiconductor substrate increases, causing the degradation in quality of the dielectric layer.

### DISCLOSURE

### Technical Problem

An aspect of the present invention is directed to provide a capacitor deposition apparatus and a method of depositing a dielectric layer deposition by using the same, which prevent a surface of a dielectric layer from being deteriorated due to a vacuum break.

Another aspect of the present invention is directed to provide a capacitor deposition apparatus and a method of depositing a dielectric layer deposition by using the same, which prevent the quality of a dielectric layer from being degraded due to a physical stress occurring when a semiconductor substrate is being loaded and unloaded.

### Technical Solution

In an aspect of the present invention, there is provided a capacitor deposition apparatus including: a first chamber forming a first dielectric layer, a second dielectric layer, and a third dielectric layer on a substrate on which an electrode is formed; a second chamber forming a metal layer on the third dielectric layer; and a third chamber connecting the first chamber and the second chamber to a vacuum state.

In another aspect of the present invention, there is provided a method of depositing a dielectric layer including: forming a first dielectric layer on a substrate on which an electrode is formed; forming a second dielectric layer on the first dielectric layer; and forming a third dielectric layer on the second dielectric layer, wherein the forming of the first dielectric layer, the forming of the second dielectric layer, and the forming of the third dielectric layer are performed in the same chamber.

In another aspect of the present invention, there is provided a method of depositing a dielectric layer including: forming a first dielectric layer on a substrate on which an electrode is formed; forming a second dielectric layer on the first dielectric layer; forming a third dielectric layer on the second dielectric layer; and forming a metal layer on the third dielectric layer, wherein the first to third dielectric layers and the metal layer are formed without being exposed to air.

The forming of the first dielectric layer, the forming of the second dielectric layer, and the forming of the third dielectric layer may be repeatedly performed.

The first dielectric layer and the third dielectric layer may be formed of the same material.

The first dielectric layer and the second dielectric layer are formed of the same material.

The second dielectric layer and the third dielectric layer may be formed of the same material.

The first to third dielectric layers may each be formed through one of a thermal treatment process, a first plasma processing process, and a second plasma processing process of performing plasma processing with plasma power higher than plasma power of the first plasma processing process.

The first to third dielectric layers may each be formed through one of an oxide deposition process and a nitride deposition process.

The method may further include, between the forming of the first dielectric layer and the forming of the second dielectric layer, performing plasma processing on the first dielectric layer.

The method may further include, between the forming of the second dielectric layer and the forming of the third dielectric layer, performing plasma processing on the second dielectric layer.

The method may further include repeating the forming of the first dielectric layer and the performing of the plasma processing on the first dielectric layer.

The method may further include repeating the forming of the second dielectric layer and the performing of the plasma processing on the second dielectric layer.

The first to third dielectric layers may have different crystalline structures.

One or more of the first to third dielectric layers may be repeatedly deposited.

A dielectric layer deposition process and a plasma processing process may be performed in the first chamber.

The first to third dielectric layers may each include one of SiO2, Al2O3, GeO2, SrO, HfSiOx, Y2O3, ZrO2, Ta2O5, CeO2, La2O3, LaAlO3, NMD, TiO2, and STO.

The method may further include, between the forming of the third dielectric layer and the forming of the metal layer, performing plasma processing on the third dielectric layer.

The method may further include repeating the forming of the third dielectric layer and the performing of the plasma processing on the third dielectric layer.

The forming of the first dielectric layer and the forming of the third dielectric layer may be performed in the same chamber.

In another aspect of the present invention, there is provided a capacitor deposition apparatus including: a first chamber forming a first dielectric layer and a third dielectric layer on a substrate on which an electrode is formed; a second chamber forming a second dielectric layer between the first dielectric layer and the third dielectric layer; a third chamber forming a metal layer on the third dielectric layer; and a fourth chamber connecting the first to third chambers to a vacuum state.

A process temperature of the first chamber may differ from a process temperature of the second chamber.

The process temperature of the first chamber may be 350□, and the process temperature of the second chamber may be 410□.

The first to third dielectric layers and the metal layer may be formed without being exposed to air.

A dielectric layer deposition process and a plasma processing process may be performed in each of the first chamber and the second chamber.

The first to third dielectric layers may each include one of SiO2, Al2O3, GeO2, SrO, HfSiOx, Y2O3, ZrO2, Ta2O5, CeO2, La2O3, LaAlO3, NMD, TiO2, and STO.

### Advantageous Effects

According to the embodiments of the present invention, the vacuum break corresponding to a state deviating from the vacuum state cannot exist between an operation of forming the third dielectric layer and an operation of forming the second electrode. As a result, the surface of the dielectric layer is prevented from being deteriorated due to the vacuum break. Accordingly, the interface characteristic between the third dielectric layer and the second electrode is prevented from being degraded, thereby preventing a reduction in capacity of the capacitor.

Moreover, according to the embodiments of the present invention, the vacuum break corresponding to a state deviating from the vacuum state cannot exist between an operation of forming the first dielectric layer, an operation of forming the second dielectric layer, an operation of forming the third dielectric layer, and an operation of forming the second electrode. As a result, the surface of each of the first to third dielectric layers is prevented from being deteriorated due to the vacuum break. Accordingly, the interface characteristic between the first dielectric layer and the second dielectric layer, between the second dielectric layer and the third dielectric layer, and between the third dielectric layer and the second electrode is prevented from being degraded, thereby preventing a reduction in capacity of the capacitor.

Moreover, according to the embodiments of the present invention, since the first to third dielectric layers are formed in the same chamber, the number of times the semiconductor substrate is loaded and unloaded is reduced in comparison with a case where the first to third dielectric layers are respectively formed in different chambers. Accordingly, the quality of the dielectric layer is prevented from being degraded due to a physical stress occurring when the semiconductor substrate is being loaded and unloaded.

Moreover, according to the embodiments of the present invention, the first to third dielectric layers may be formed in the same chamber, and in this case, the second dielectric layer may be formed at the first temperature instead of the second temperature. Also, the second dielectric layer being formed at the second temperature is preferable, but since the second dielectric layer is formed at the first temperature, plasma processing may be performed for the second dielectric layer, for compensating for temperature energy corresponding to a difference between the first temperature and the second temperature. Particularly, since an oxygen gas is supplied to the second dielectric layer and plasma processing is performed for the second dielectric layer, the temperature energy is compensated for, and the interface of the second dielectric layer is solidified.

Moreover, according to the embodiments of the present invention, N2 plasma processing may be performed for the surface of the first electrode formed on the semiconductor substrate. Accordingly, the interface of the surface of the first electrode is improved, thereby improving the interface characteristic between the first electrode and the first dielectric layer.

### BRIEF DESCRIPTION OF DRAWINGS

FIG. 1 is a cross-sectional view illustrating a capacitor of a semiconductor device according to an embodiment of the present invention;

FIG. 2 is a flowchart illustrating a method of manufacturing a capacitor having a high dielectric constant according to an embodiment of the present invention;

FIG. 3 is an exemplary diagram illustrating a deposition apparatus applied to a method of manufacturing a capacitor having a high dielectric constant according to an embodiment of the present invention;

FIG. 4 is a flowchart illustrating a method of manufacturing a capacitor having a high dielectric constant according to another embodiment of the present invention; and

FIG. 5 is an exemplary diagram illustrating a deposition apparatus applied to a method of manufacturing a capacitor having a high dielectric constant according to another embodiment of the present invention.

### DETAILED DESCRIPTION OF EMBODIMENTS OF INVENTION

Reference will now be made in detail to the exemplary embodiments of the present invention, examples of which are illustrated in the accompanying drawings. Wherever possible, the same reference numbers will be used throughout the drawings to refer to the same or like parts.

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims.

A shape, a size, a ratio, an angle, and a number disclosed in the drawings for describing embodiments of the present invention are merely an example, and thus, the present invention is not limited to the illustrated details. Like reference numerals refer to like elements throughout. In the following description, when the detailed description of the relevant known function or configuration is determined to unnecessarily obscure the important point of the present invention, the detailed description will be omitted. In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a time relationship, for example, when the temporal order is described as ‘after˜’, ‘subsequent˜’, ‘next˜’, and ‘before˜’, a case which is not continuous may be included unless ‘just’ or ‘direct’ is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Features of various embodiments of the present invention may be partially or overall coupled to or combined with each other, and may be variously inter-operated with each other and driven technically as those skilled in the art can sufficiently understand. The embodiments of the present invention may be carried out independently from each other, or may be carried out together in co-dependent relationship.

Hereinafter, exemplary embodiments of the present invention will be described in detail with reference to the accompanying drawings.

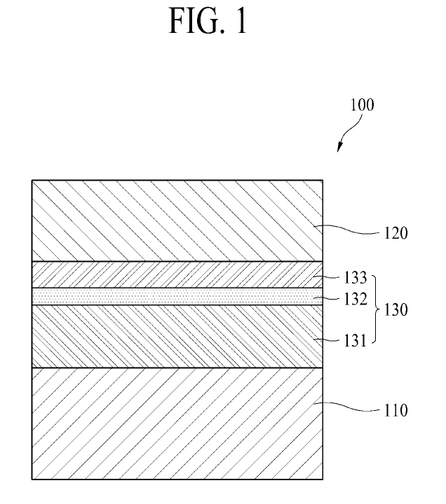

FIG. 1 is a cross-sectional view illustrating a capacitor 100 of a semiconductor device according to an embodiment of the present invention. Referring to FIG. 1, the capacitor 100 of the semiconductor device according to an embodiment of the present invention may include a first electrode 110, a second electrode 120, and a dielectric layer 130.

The first electrode 110 may be a lower electrode, and the second electrode 120 may be an upper electrode. The first and second electrodes 110 and 120 may each be an electrode which is patterned in a certain pattern. The first and second electrodes 110 and 120 may be formed of titanium nitride (TiN), but is not limited thereto.

The dielectric layer 130 may include a plurality of high-K dielectric layers. For example, as illustrated in FIG. 1, the dielectric layer 130 may include first to third dielectric layers 131 to 133.

An example where the first and third dielectric layers 131 and 133 are formed of the same high-K A material and the second dielectric layer 132 is formed of a high-K B material is described, but the present embodiment is not limited thereto. In other embodiments, the first and second dielectric layers 131 and 132 may be formed of the same high-K A material, and the third dielectric layer 133 may be formed of the high-K B material. In other embodiments, the second and third dielectric layers 132 and 133 may be formed of the same high-K A material, and the first dielectric layer 131 may be formed of the high-K B material.

The high-K A material and the high-K B material may each be one of SiO2, Al2O3, GeO2, SrO, HfSiOx, Y2O3, ZrO2, Ta2O5, CeO2, La2O3, LaAlO3, NMD, TiO2, and STO. That is, the first to third dielectric layers 131 to 133 may be formed through an oxide deposition process or a nitride deposition process.

The first dielectric layer 131 may be formed on the first electrode 110. The first dielectric layer 131 may have a thickness of about 60 Å and may be formed as a tetragonal crystalline layer.

The second dielectric layer 132 may be formed on the first dielectric layer 131. The second dielectric layer 132 may have a thickness of about 5 Å to 8 Å.

The third dielectric layer 133 may be formed on the second dielectric layer 132. The third dielectric layer 133 may have a thickness of about 20 Å to 30 Å and may be formed as an amorphous layer.

If the dielectric layer 130 is formed in a three-layer structure which includes the first dielectric layer 131 including a tetragonal crystalline layer, the second dielectric layer 132, and the third dielectric layer 133 including an amorphous layer as in an embodiment of the present invention, the capacitor 100 may have a high dielectric constant as expressed in Equation (1), thereby increasing a capacity of the capacitor 100.

The first dielectric layer 131 may be formed through thermal treatment performed at a certain temperature, the second dielectric layer 132 may be formed through first plasma processing performed at a certain temperature, and the third dielectric layer 133 may be formed through second plasma processing performed at a certain temperature. Alternatively, the first dielectric layer 131 may be formed through the thermal treatment performed at the certain temperature, the second dielectric layer 132 may be formed through the second plasma processing performed at the certain temperature, and the third dielectric layer 133 may be formed through the first plasma processing performed at the certain temperature. The second plasma processing may be performed with plasma power higher than that of the first plasma processing. Based on the plasma power, a density of a dielectric layer may vary, and a content of impurities may vary. Due to a crystallization degree difference based on a content of impurities and a density difference of the dielectric layer, a difference occurs in current leakage characteristic of the dielectric layer.

Moreover, the first to third dielectric layers 131 to 133 may be repeatedly deposited. Alternatively, one or more of the first to third dielectric layers 131 to 133 may be repeatedly deposited.

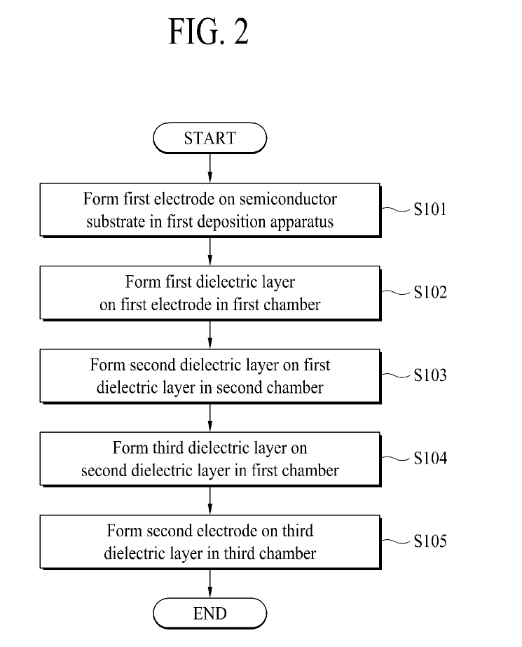

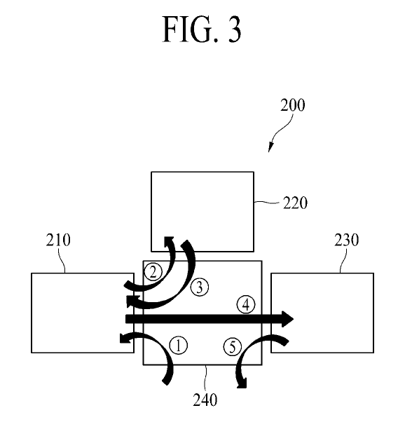

FIG. 2 is a flowchart illustrating a method of manufacturing a capacitor having a high dielectric constant according to an embodiment of the present invention. FIG. 3 is an exemplary diagram illustrating a deposition apparatus applied to a method of manufacturing a capacitor having a high dielectric constant according to an embodiment of the present invention.

Referring to FIG. 3, a second deposition apparatus 200 may include first and second chambers 210 and 220, a third chamber (a transfer chamber) 240 corresponding to the transfer chamber, and a fourth chamber 230. The first chamber 210 may be a chamber for forming the first and third dielectric layers 131 and 133. Since the first and third dielectric layers 131 and 133 are formed of the same material, the first and third dielectric layers 131 and 133 may be formed in the same chamber, namely, the first chamber 210. The second chamber 220 may be a chamber for forming the second dielectric layer 132. The first and second chambers 210 and 220 may be chambers that enable a dielectric layer deposition process and a plasma processing process to be performed. The third chamber (the transfer chamber) 240 may be a chamber for transferring a semiconductor substrate to the first, second, and fourth chambers 210, 220 and 230 and connecting the first, second, and fourth chambers 210, 220 and 230 to a vacuum state. The fourth chamber 230 may be a chamber for forming the second electrode 120. The first to fourth chambers 210, 220, 240 and 230 may be in the vacuum state. Hereinafter, for convenience of description, the third chamber 240 may be referred to as a transfer chamber.

Hereinafter, a method of manufacturing a capacitor having a high dielectric constant according to an embodiment of the present invention will be described with reference to FIGS. 2 and 3. In FIGS. 2 and 3, for convenience of description, an example where the first and third dielectric layers 131 and 133 are formed of the same high-K A material and the second dielectric layer 132 is formed of the high-K B material is described.

First, as illustrated in FIG. 2, the first electrode 110 may be formed on the semiconductor substrate in the vacuum state by using a first deposition apparatus. The first electrode 110 may be formed of TiN, but is not limited thereto.

If the first electrode 110 is a pattern electrode which is patterned in a certain shape, the semiconductor substrate on which the first electrode 110 is formed may be wet-cleaned for removing foreign materials such as particles and/or the like. Also, after the semiconductor substrate on which the first electrode 110 is formed is wet-cleaned, N2 plasma processing may be performed for improving an interface of a surface of the first electrode 110. When the interface of the surface of the first electrode 110 is improved by performing the N2 plasma processing, interface characteristic between the first electrode 110 and the first dielectric layer 131 is improved. (S101 of FIG. 2)

Second, the semiconductor substrate on which the first electrode 110 is formed may be transferred to the first chamber 210 of the second deposition apparatus 200 as in \textcircled{1} of FIG. 3, for forming the first dielectric layer 131. As illustrated in FIG. 2, the first dielectric layer 131 may be formed on the first electrode 110 in the first chamber 210 which is in the vacuum state. The first dielectric layer 131 may have a thickness of about 60 Å and may be a tetragonal crystalline layer, but is not limited thereto.

The first dielectric layer 131 may be formed at a first temperature, for example, a high temperature of about 350□. The first dielectric layer 131 may be repeatedly deposited.

A first plasma operation, which performs plasma processing while the first dielectric layer 131 is being deposited or after the first dielectric layer 131 is deposited, may be performed between operation S102 and operation S103. In this case, the first dielectric layer 131 may be formed by repeating an operation of depositing the first dielectric layer 131 and performing plasma processing on the first dielectric layer 131. (S102 of FIG. 2)

Third, the semiconductor substrate on which the first dielectric layer 131 is formed may be transferred from the first chamber 210 to the second chamber 220 as in \textcircled{2} of FIG. 3, for forming the second dielectric layer 132. In detail, the semiconductor substrate on which the first dielectric layer 131 is formed may be transferred from the first chamber 210 to the second chamber 220 through the transfer chamber 240. At this time, since the transfer chamber 240 is in the vacuum state, the semiconductor substrate on which the first dielectric layer 131 is formed may be transferred from the first chamber 210 to the second chamber 220 without undergoing the vacuum break corresponding to a state deviating from the vacuum state.

As illustrated in FIG. 2, the second dielectric layer 132 may be formed on the first dielectric layer 131 in the second chamber 220 which is in the vacuum state. The second dielectric layer 132 may have a thickness of about 5 Å to 8 Å. The second dielectric layer 132 may be formed at a second temperature (for example, a high temperature of about 450□) higher than the first temperature. The second dielectric layer 132 may be repeatedly deposited.

Alternatively, the second dielectric layer 132 may be formed at the first temperature. The second dielectric layer 132 may be formed at a second temperature (for example, about 450□), and thus, in a case where the second dielectric layer 132 is formed at the first temperature, it is required to compensate for temperature energy corresponding to a difference between the first temperature and the second temperature. In order to compensate for the temperature energy corresponding to the difference between the first temperature and the second temperature, a second plasma operation which performs plasma processing while the second dielectric layer 132 is being deposited or after the second dielectric layer 132 is deposited may be performed between operation S103 and operation S104. In the related art, a process of forming the second dielectric layer 132 and plasma processing are performed in different chambers. However, in an embodiment of the present invention, a process of forming the second dielectric layer 132 and a plasma processing process may all be performed in the first chamber 310. For example, the first chamber 310 may perform plasma processing with radio frequency (RF) power of 1 kw for about 20 sec to 300 sec in forming the second dielectric layer 132, thereby compensating for temperature energy. The temperature energy may be compensated for by adjusting the RF power. In this case, the second dielectric layer 132 may be formed by repeating an operation of depositing the second dielectric layer 132 and performing plasma processing on the second dielectric layer 132. (S103 of FIG. 2)

Fourth, the semiconductor substrate on which the second dielectric layer 132 is formed may be again transferred from the second chamber 220 to the first chamber 210 as in \textcircled{3} of FIG. 3, for forming the third dielectric layer 133. In detail, the semiconductor substrate on which the second dielectric layer 132 is formed may be transferred from the second chamber 220 to the first chamber 210 through the transfer chamber 240. At this time, since the transfer chamber 240 is in the vacuum state, the semiconductor substrate on which the second dielectric layer 132 is formed may be transferred from the second chamber 220 to the first chamber 210 without undergoing the vacuum break corresponding to a state deviating from the vacuum state.

As illustrated in FIG. 2, the third dielectric layer 133 may be formed on the second dielectric layer 132 in the first chamber 210 which is in the vacuum state. The third dielectric layer 133 may have a thickness of about 20 Å to 30 Å and may be an amorphous layer, but is not limited thereto.

The third dielectric layer 133 may be formed at the first temperature, for example, a high temperature of about 350 □. The third dielectric layer 133 may be repeatedly deposited.

A third plasma operation, which performs plasma processing while the third dielectric layer 133 is being deposited or after the third dielectric layer 133 is deposited, may be performed between operation S104 and operation S105. In this case, the third dielectric layer 133 may be formed by repeating an operation of depositing the third dielectric layer 133 and performing plasma processing on the third dielectric layer 133. (S104 of FIG. 2)

Fifth, the semiconductor substrate on which the third dielectric layer 133 is formed may be transferred from the first chamber 210 to the fourth chamber 230 as in \textcircled{4} of FIG. 3, for forming the second dielectric layer 132. In detail, the semiconductor substrate on which the third dielectric layer 133 is formed may be transferred from the first chamber 210 to the fourth chamber 230 through the transfer chamber 240. At this time, since the transfer chamber 240 is in the vacuum state, the semiconductor substrate on which the third dielectric layer 133 is formed may be transferred from the first chamber 210 to the fourth chamber 230 without undergoing the vacuum break corresponding to a state deviating from the vacuum state.

As illustrated in FIG. 2, the second electrode 120 may be formed on the third dielectric layer 133 in the fourth chamber 230 which is in the vacuum state. The second electrode 120 may be formed of TiN, but is not limited thereto. The semiconductor substrate on which the second electrode 120 is formed may be transferred from the fourth chamber 230 to a transfer apparatus as in \textcircled{5} of FIG. 3. (S105 of FIG. 2)

As described above, in an embodiment of the present invention, the first to third dielectric layers 131 to 133 and the second electrode 120 may be formed in the second deposition apparatus 200 including the first, second, and fourth chambers 210, 220 and 230 and the third chamber (the transfer chamber) 240 which are in the vacuum state. Therefore, in an embodiment of the present invention, the vacuum break corresponding to a state deviating from the vacuum state does not exist when forming the first to third dielectric layers 131 to 133 and the second electrode 120. That is, the first to third dielectric layers 131 to 133 may be formed without being exposed to air in a manufacturing process. Therefore, in an embodiment of the present invention, the first to third dielectric layers 131 to 133 are not exposed to air and thus are not deteriorated, thereby preventing a reduction in interface characteristic between the first to third dielectric layers 131 to 133.

Particularly, in the related art, a thickness of each of the first to third dielectric layers 131 to 133 is thickly set for preventing a reduction in interface characteristic between the first to third dielectric layers 131 to 133, and for this reason, as described above through Equation (1), a capacity of the capacitor 100 is reduced. On the other hand, in an embodiment of the present invention, the interface characteristic between the first to third dielectric layers 131 to 133 is prevented from being degraded, and thus, the thickness of each of the first to third dielectric layers 131 to 133 is set thinner than the related art, thereby solving a problem where the capacity of the capacitor 100 is reduced.

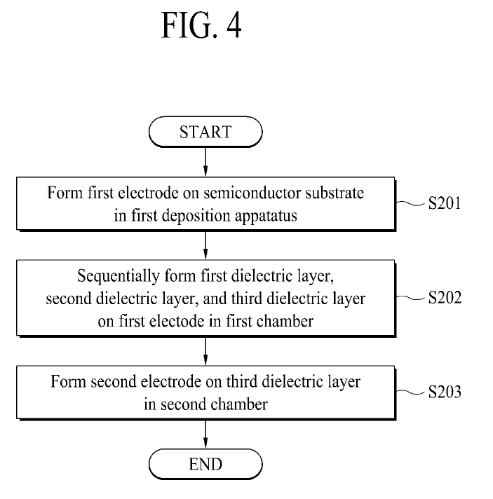

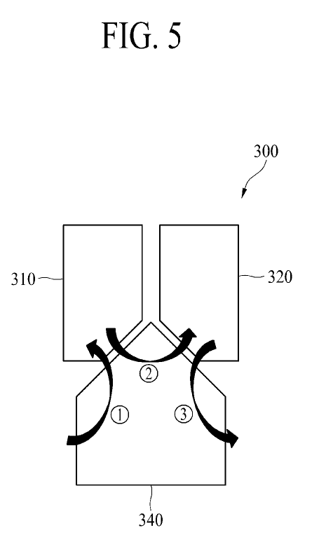

FIG. 4 is a flowchart illustrating a method of manufacturing a capacitor having a high dielectric constant according to another embodiment of the present invention. FIG. 5 is an exemplary diagram illustrating a deposition apparatus applied to a method of manufacturing a capacitor having a high dielectric constant according to another embodiment of the present invention.

Referring to FIG. 5, a second deposition apparatus 300 may include a first chamber 310, a second chambers 320, and a third chamber (a transfer chamber) 340. The first chamber 310 may be a chamber for forming the first and third dielectric layers 131 and 133 and the second dielectric layer 132. That is, the first and third dielectric layers 131 and 133 and the second dielectric layer 132 may be formed in the same chamber, namely, the first chamber 310. The first chamber 310 may be a chamber that enables a dielectric layer deposition process and a plasma processing process to be performed. The second chamber 320 may be a chamber for forming the second electrode 120. The third chamber (the transfer chamber) 340 may be a chamber for transferring a semiconductor substrate to the first and second chambers 310 and 320 and connecting the first and second chambers 310 and 320 to a vacuum state. The first to third chambers 310, 320 and 230 may be in the vacuum state. Hereinafter, for convenience of description, the third chamber 340 may be referred to as a transfer chamber.

Hereinafter, a method of manufacturing a capacitor having a high dielectric constant according to another embodiment of the present invention will be described with reference to FIGS. 4 and 5. In FIGS. 4 and 5, for convenience of description, an example where the first and third dielectric layers 131 and 133 are formed of the same high-K A material and the second dielectric layer 132 is formed of the high-K B material is described.

First, as illustrated in FIG. 4, the first electrode 110 may be formed on the semiconductor substrate in the vacuum state by using the first deposition apparatus. The first electrode 110 may be formed of TiN, but is not limited thereto.

If the first electrode 110 is a pattern electrode which is patterned in a certain shape, the semiconductor substrate on which the first electrode 110 is formed may be wet-cleaned for removing foreign materials such as particles and/or the like. Also, after the semiconductor substrate on which the first electrode 110 is formed is wet-cleaned, N2 plasma processing may be performed for improving an interface of a surface of the first electrode 110. When the interface of the surface of the first electrode 110 is improved by performing the N2 plasma processing, interface characteristic between the first electrode 110 and the first dielectric layer 131 is improved. (S201 of FIG. 4)

Second, the semiconductor substrate on which the first electrode 110 is formed may be transferred to the first chamber 310 of the second deposition apparatus 300 as in \textcircled{1} of FIG. 5, for forming the first dielectric layer 131. As illustrated in FIG. 4, the first dielectric layer 131, the second dielectric layer 132, and the third dielectric layer 133 may be sequentially formed on the first electrode 110 in the first chamber 310 which is in the vacuum state. Therefore, the first to third dielectric layers 131 to 133 may be formed without being exposed to air in a manufacturing process.

First, the first dielectric layer 131 may be formed on the first electrode 110. The first dielectric layer 131 may have a thickness of about 60 Å and may be a tetragonal crystalline layer, but is not limited thereto. The first dielectric layer 131 may be formed at the first temperature, for example, a high temperature of about 300 □. The first dielectric layer 131 may be repeatedly deposited.

Plasma processing may be performed while the first dielectric layer 131 is being deposited or after the first dielectric layer 131 is deposited. In this case, the first dielectric layer 131 may be formed by repeating an operation of depositing the first dielectric layer 131 and performing plasma processing on the first dielectric layer 131.

Subsequently, the second dielectric layer 132 may be formed on the first dielectric layer 131. The second dielectric layer 132 may have a thickness of about 5 Å to 8 Å, but is not limited thereto. As illustrated in FIG. 5, in a case where the second dielectric layer 132 is formed in the first chamber 310 which is the same as a chamber where the first dielectric layer 131 is formed, the second dielectric layer 132 may be formed at the first temperature (for example, a high temperature of about 300□).

The second dielectric layer 132 may be formed at the second temperature (for example, about 400 □), and thus, in a case where the second dielectric layer 132 is formed at the first temperature, it is required to compensate for temperature energy corresponding to a difference between the first temperature and the second temperature. In order to compensate for the temperature energy corresponding to the difference between the first temperature and the second temperature, in the present embodiment, the second dielectric layer 132 may be formed in the first chamber 310 and then may be supplied with an oxygen (O2)-containing gas, and plasma processing may be performed for the second dielectric layer 132. In the related art, a process of forming the second dielectric layer 132 and plasma processing are performed in different chambers. However, in the present embodiment, a process of forming the second dielectric layer 132 and a plasma processing process may all be performed in the first chamber 310. For example, the first chamber 310 may perform plasma processing with the RF power of 1 kw for about 20 sec to 300 sec in forming the second dielectric layer 132, thereby compensating for temperature energy. The temperature energy may be compensated for by adjusting the RF power.

The second dielectric layer 132 may be repeatedly deposited. For example, the second dielectric layer 132 may be formed by repeating an operation of depositing the second dielectric layer 132 at the first temperature and performing plasma processing on the second dielectric layer 132.

Subsequently, the third dielectric layer 133 may be formed on the second dielectric layer 132. The third dielectric layer 133 may have a thickness of about 20 Å to 30 Å and may be an amorphous layer, but is not limited thereto. The third dielectric layer 133 may be repeatedly deposited.

Plasma processing may be performed while the third dielectric layer 133 is being deposited or after the third dielectric layer 133 is deposited. In this case, the third dielectric layer 133 may be formed by repeating an operation of depositing the third dielectric layer 133 and performing plasma processing on the third dielectric layer 133. (S202 of FIG. 4)

Third, the semiconductor substrate on which the first to third dielectric layers 131 to 133 are formed may be transferred from the first chamber 310 to the second chamber 320 as in \textcircled{2} of FIG. 5, for forming the second electrode 120. In detail, the semiconductor substrate on which the first to third dielectric layers 131 to 133 are formed may be transferred from the first chamber 310 to the second chamber 320 through the transfer chamber 340. At this time, since the transfer chamber 340 is in the vacuum state, the semiconductor substrate on which the first to third dielectric layers 131 to 133 are formed may be transferred from the first chamber 310 to the second chamber 320 without undergoing the vacuum break corresponding to a state deviating from the vacuum state.

As illustrated in FIG. 4, the second electrode 120 may be formed on the third dielectric layer 133 in the second chamber 320 which is in the vacuum state. The second electrode 120 may be formed of TiN, but is not limited thereto. The semiconductor substrate on which the second electrode 120 is formed may be transferred from the second chamber 320 to the transfer apparatus as in \textcircled{3} of FIG. 5. (S203 of FIG. 4)

As described above, in the present embodiment, the first to third dielectric layers 131 to 133 and the second electrode 120 may be formed in the second deposition apparatus 300 including the first and second chambers 310 and 320 and the third chamber (the transfer chamber) 340 which are in the vacuum state. Therefore, in the present embodiment, the vacuum break corresponding to a state deviating from the vacuum state does not exist when forming the first to third dielectric layers 131 to 133 and the second electrode 120. That is, the first to third dielectric layers 131 to 133 may be formed without being exposed to air in a manufacturing process. Therefore, in the present embodiment, the first to third dielectric layers 131 to 133 are not exposed to air and thus are not deteriorated, thereby preventing a reduction in interface characteristic between the first to third dielectric layers 131 to 133.

Particularly, in the related art, a thickness of each of the first to third dielectric layers 131 to 133 is thickly set for preventing a reduction in interface characteristic between the first to third dielectric layers 131 to 133, and for this reason, as described above through Equation (1), a capacity of the capacitor 100 is reduced. On the other hand, in the present embodiment, the interface characteristic between the first to third dielectric layers 131 to 133 is prevented from being degraded, and thus, the thickness of each of the first to third dielectric layers 131 to 133 is set thinner than the related art, thereby solving a problem where the capacity of the capacitor 100 is reduced.

Moreover, according to the present embodiment, since the first to third dielectric layers 131 to 133 are formed in the same chamber (i.e., the first chamber 310), the number of times the semiconductor substrate is loaded and unloaded is reduced in comparison with a case where the first to third dielectric layers 131 to 133 are respectively formed in different chambers. Accordingly, the quality of the dielectric layer is prevented from being degraded due to a physical stress occurring when the semiconductor substrate is being loaded and unloaded.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. (canceled)

2. (canceled)

3. A method of depositing a dielectric layer, the method comprising:
forming a first dielectric layer on a substrate on which an electrode is formed;
forming a second dielectric layer on the first dielectric layer;
forming a third dielectric layer on the second dielectric layer; and
forming a metal layer on the third dielectric layer,
wherein the first to third dielectric layers and the metal layer are formed without being exposed to air.

4. The method of claim 3, wherein the forming of the first dielectric layer, the forming of the second dielectric layer, and the forming of the third dielectric layer are repeatedly performed.

5. The method of claim 3, wherein the first dielectric layer and the third dielectric layer are formed of the same material.

6. The method of claim 3, wherein the first dielectric layer and the second dielectric layer are formed of the same material.

7. The method of claim 3, wherein the second dielectric layer and the third dielectric layer are formed of the same material.

8. The method of claim 3, wherein the first to third dielectric layers are each formed through one of a thermal treatment process, a first plasma processing process, and a second plasma processing process of performing plasma processing with plasma power higher than plasma power of the first plasma processing process.

9. The method of claim 3, wherein the first to third dielectric layers are each formed through one of an oxide deposition process and a nitride deposition process.

10. The method of claim 3, further comprising: between the forming of the first dielectric layer and the forming of the second dielectric layer, performing plasma processing on the first dielectric layer.

11. The method of claim 3, further comprising: between the forming of the second dielectric layer and the forming of the third dielectric layer, performing plasma processing on the second dielectric layer.

12. The method of claim 10, further comprising: repeating the forming of the first dielectric layer and the performing of the plasma processing on the first dielectric layer.

13. The method of claim 11, further comprising: repeating the forming of the second dielectric layer and the performing of the plasma processing on the second dielectric layer.

14. The method of claim 3, wherein the first to third dielectric layers have different crystalline structures.

15. The method of claim 14, wherein one or more of the first to third dielectric layers are repeatedly deposited.

16. (canceled)

17. The method of claim 3, wherein the first to third dielectric layers each comprise one of SiO₂, Al₂O₃, GeO₂, SrO, HfSiOx, Y₂O₃, ZrO₂, Ta₂O₅, CeO₂, La₂O₃, LaAlO₃, NMD, TiO₂, and STO.

18. The method of claim 3, further comprising: between the forming of the third dielectric layer and the forming of the metal layer, performing plasma processing on the third dielectric layer.

19. The method of claim 18, further comprising: repeating the forming of the third dielectric layer and the performing of the plasma processing on the third dielectric layer.

20. The method of claim 3, wherein the forming of the first dielectric layer and the forming of the third dielectric layer are performed in the same chamber.

21-26. (canceled)
